(19) United States
(12) Patent Application Publication
(10) Pub. No.: US 2006/0289305 A1
(43) Pub. Date: Dec. 28, 2006

(54) Centering mechanism for aligning sputtering target tiles

(75) Inventor: John M. White, Hayward, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc.

(21) Appl. No.: 11/167,628

(22) Filed: Jun. 27, 2005

(51) Int. Cl. C23C 14/00

(52) U.S. Cl. 204/298.12

(57) ABSTRACT

In a sputtering target assembly comprising a plurality of tiles bonded to a target backing plate with gaps formed between the tiles, centering mechanisms for aligning and centering each of the tiles to the backing plate. The centering mechanism for each tiles can comprise a two or three grooves formed in the backing plate along axes intersecting near the tile center and slidably accommodating corresponding pins extending from the tile. Alternately, a pin and groove can be combined with another tile pin and a circular hole in the backing plate near the tile center.

### FIELD OF THE INVENTION

The invention relates generally to sputtering of materials. In particular, the invention relates to sputtering targets composed of multiple tiles.

### BACKGROUND ART

Sputtering, alternatively called physical vapor deposition (PVD), is the most prevalent method of depositing layers of metals and related materials in the fabrication of semiconductor integrated circuits. Sputtering is now being applied to the fabrication of flat panel displays (FPDs) based upon thin film transistors (TFTs). FPDs may assume several forms based upon liquid crystal devices (LCDs), plasma displays, field emission displays, and organic light emitting diodes (OLEDs) FPDs are typically fabricated on thin rectangular sheets of glass although the technology is being developed for polymer and other types of substrates. A layer of silicon is deposited on the glass panel or other substrates and silicon transistors are formed in and around the silicon layer by techniques well known in the fabrication of electronic integrated circuits. The electronic circuitry formed on the substrate is used to drive optical elements, such as LCDs, OLEDs, or other elements, developed in or subsequently mounted on the substrate.

Size constitutes one most apparent difference between electronic integrated circuits and flat panel displays and in the equipment used to fabricate them. Demaray et al. disclose many of the distinctive features of flat panel sputtering apparatus in U.S. Pat. No. 6,199,259, incorporated herein by reference. That equipment was originally designed for panels having a size of approximately 400 mm×600 mm. Because of the increasing sizes of flat panel displays being produced and the economy of scale realized when multiple displays are fabricated on a single glass panel and thereafter diced, the size of the panels has been continually increasing. The increase applies also to other types of substrates. Flat panel fabrication equipment is commercially available for sputtering onto panels having a minimum size of 1.8 m and equipment is being contemplated for panels having sizes of 2 m×2 m and even larger.

For many reasons, the target for flat panel sputtering is usually formed of a sputtering layer of the target material bonded to a target backing plate, typically formed of titanium. One problem arising from the increased panel sizes and hence increased target sizes is the difficulty of obtaining target material of proper quality in the larger sizes. Refractory materials such as chromium are particularly difficult materials to fabricate in large sizes. The size problem has been addressed by forming the target sputtering layer from multiple target tiles. Targets formed from multiple tiles each occupying less than the total area of the substrate to be sputter coated have introduced several problems not experienced with laterally homogeneous targets.

### SUMMARY OF THE INVENTION

A centering mechanism for aligning a plurality of sputtering tiles bonded to a target backing plate in a one- or two-dimensional array with gaps therebetween. The resultant target assembly may be used in a magnetron sputter reactor, particularly one intended for flat panel displays.

The centering mechanism for each tile may comprise at least one pin extending from the tile toward the backing plate and a corresponding groove formed along a centering axis in the backing plate slidably accommodating the pin.

There may be two, three, or possibly more pairs of pins and grooves with the groove axes preferably intersecting near the target center.

Alternately, one pair of pin and groove may cooperate with another pin in the tile and a circular recess in the backing plate pivotally capturing the added pin and located along the axis of the groove, preferably at the tile center.

### BRIEF DESCRIPTION OF THE DRAWINGS

FIG. 1 is a schematic cross-sectional view of a conventional plasma sputter reactor.

FIG. 2 is bottom plan view of a target assembly including target tiles bonded to backing plate.

FIG. 3 is a schematic plan view of a first embodiment of the invention including centering mechanisms for centering target tiles on a backing plate.

FIG. 4 is a cross-sectional view of part of the centering mechanism of the first embodiment.

FIG. 5 is a cross-sectional view of a variant of the first embodiment.

FIG. 6 is a schematic plan view of a second embodiment of the invention including a different type of centering mechanism.

FIG. 7 is a cross-sectional view of part of the second embodiment.

### DETAILED DESCRIPTION OF THE PREFERRED EMBODIMENTS

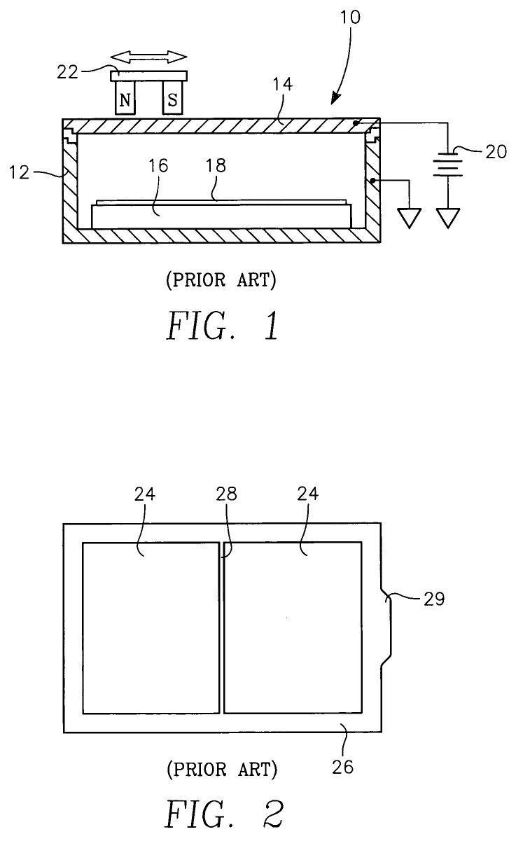

The invention may be practiced in sputtering apparatus such as a sputtering chamber 10, schematically illustrated in the cross-sectional view of FIG. 1, which includes a vacuum chamber 12, a target 14 sealed to but isolated from the electrically grounded chamber 12, and a pedestal 16 supporting a panel or other substrate 18 to be sputter coated. The target 14 includes a surface layer of the material to be sputtered onto the panel 18. An argon working gas is admitted into the chamber with a pressure in the milliTorr range. A power supply 20 electrically biases the target 14 to a negative voltage of a few hundred volts, causing the argon gas to discharge into a plasma. The positive argon ions are attracted to the negatively biased target 14 and sputter target atoms from it. A magnetron 22 is scanned over the back of the target 14 to intensify the plasma and increase the sputtering rate. Some of the target atoms strike the panel 18 and form a thin film of the target atoms on its surface. The target 14 needs to be somewhat larger than the panel 18 being sputter coated so that its size as well has been increasing with more recent equipment. Sputtering has been applied to a large number of target materials including aluminum, copper, titanium, tantalum, chromium, and indium tin oxide (ITO) as well as other materials.

The configuration of tiles assembled to form a target will now be described. As schematically illustrated in the plan view of FIG. 2, multiple target tiles 24 are set on a backing plate 26 with a predetermined gap 28 between them. The tiles 24 are thereafter bonded to the backing plate 26. The large peripheral area of the backing plate 26 outside the tiles 24 is used to support the target 14 on the vacuum chamber 12 and an extension 29 of the backing plate 26 falls outside of the outline of the vacuum chamber 12 to provide electrical terminals and plumbing ports for the water cooling channels formed in the backing plate 26.

The arrangement of two tiles illustrated in FIG. 2 represents the simplest tile arrangement, two tiles in a linear array with a single gap between them. Demaray in the aforecited patent discloses a larger number N>2 of tiles in a linear array with (N−1) gaps between them. Tepman in U.S. patent application Ser. No. 10/863,152, filed Jun. 7, 2004 discloses a two-dimensional array of tiles with vertical and horizontally extending gaps intersecting each other. The array may be a rectangular array, a staggered array as in simple brick wall, or more complicated two-dimensional arrays including herringbone patterns. Although rectangular tiles present the simplest geometry, other tile shapes are possible, such as triangular and hexagonal tile shapes with correspondingly more complex gap arrangements.

The gap 28 between the tiles 24 must be carefully designed and maintained. Typically, the gap 28 is not filled with other material and the backing plate or material other than the target material is exposed at the bottom of the gap 28. However, if the gap 28 (or at least part of it) is maintained at no more than about 1 mm, the sputtering plasma cannot propagate into the gap because the gap is less than the plasma dark space. Because the plasma does not propagate to the bottom of the gap 28, the backing plate 26 is not sputtered. It is possible, although not preferred, that some of the gaps at some temperatures have a zero thickness as the neighboring tiles touch or press against each other.

A problem arises, however, from the not insignificant fraction of atoms that are sputtered from the front face of the target and redeposit upon the target rather than upon the deposition substrate. The sputter atoms redeposited on the planar target face are typically sputtered at a faster rate than they are redeposited so the redeposited material does not build up. On the other hand, sputter atoms may also redeposit in the gap away from the sputter plasma. Hence, the deposited material tends to develop a growing layer on the sidewalls and bottom of the gap between the tiles. The redeposited material tends to not stick well to the underlying target or backing plate. An excessive thickness of redeposited sputter material tends to flake off in sizable particles that then fall upon the substrate being sputter deposited. The particles may have size greater than features being formed in the substrate so that a single particle may cause a fatal defect in the entire large flat panel display. Clearly, the number of such particles needs to be reduced or eliminated to increase the yield of flat panel displays or other circuitry being developed in the substrate.

The number of such particles is lessened by reducing the width of the gap to less than the plasma dark space, but a finite gap is required because of the differential thermal expansion between the target tiles and the backing plate during thermal cycling during substrate processing or during tile bonding. A gap width of about 0.5 mm represents a current design thickness.

There are several methods of bonding tiles to a backing plate. Indium solder bonding is typically used for many large targets. Indium's melting point is 156° C. so the soldering process needs to be performed with both the target and backing plate held at somewhat higher temperatures. As a result, differential thermal expansion is significant during bonding. If the indium is not applied in a symmetric pattern, the non-symmetrically bonded tiles may shift during cooling so that one or more gaps may be larger than desired.

A more recently developed bonding process places a conductive elastomer or other organic adhesive between the target and backing plate. The elastomer can be cured at relatively low temperatures so that differential thermal expansion during bonding presents much less a problem and the design gap thickness may be reduced. Such elastomeric bonding services are available from Thermal Conductive Bonding, Inc. of San Jose, Calif. Nonetheless, the target assembly is still subject to some differential thermal expansion, either during the bonding process or during the operational life of the target as the target temperature rises during sputtering when power is applied to the target and falls during quiescent periods when no power is applied. Cured elastomeric adhesives are perceived to be much more pliable and deformable than indium solder joints and it is possible for tiles to walk during thermal cycling, that is, their positions at the same temperature before and after thermal cycling may change with an accompanying change in gap thicknesses.

Demaray in the aforecited patent suggests autoclaving at high temperature and pressure so the tiles and backing plate diffuse together. While autoclaving produces a very strong bond, the required high temperatures necessitates that the design gap thickness is somewhat large.

Whatever the bonding method, it is thus believed that extra precaution should be exercised in maintaining the gap widths.

To improve the relative orientation of multiple tiles, mechanical guiding means may be developed between the target tiles and the backing plate or other support structure that tend to return the tiles to mechanically defined positions on the backing plate as the tiles expand and contract relative to the backing plate.

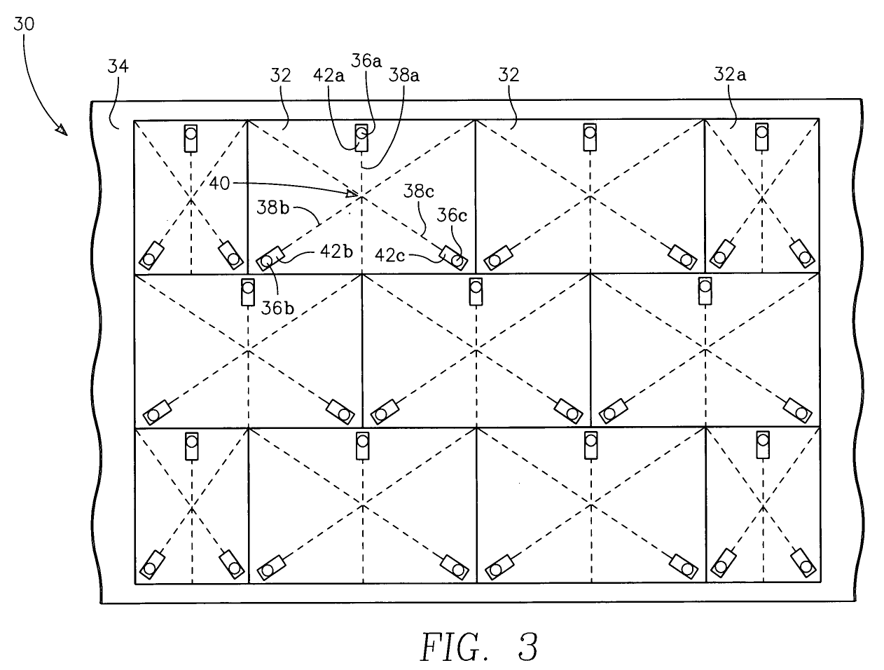

A first embodiment of the invention is illustrated schematically in plan view in FIG. 3. A target assembly 30 includes seven rectangular tiles 32 bonded to a target backing plate 34 in a two-dimensional array, which is staggered in the illustration but other one- and two-dimensional arrangements may be used. It is appreciated that for flat-panel sputtering, the tiles fill a rectangular outline of the backing plate 34 overlying the panel to be sputter coated. For the staggered configuration, half tiles 32a fill the corners or other vacancies of the full tiles 32 within a rectangular outline. Each full tile 32 includes three alignment pins 36a, 36b, 36c formed on the tile side facing the backing plate 34 and disposed on respective centering axes 38a, 38b, 38c. The first axis 38a preferably bisects the rectangular shape of the tile 32 and extends along the shorter direction of the tile 32 if the tile 32 is non-square while the other two axes 36b, 36c preferably fall on the two diagonals of the tile 32. More importantly than their location within the tile 32, the three axes 38a, 38b, 38c are inclined with respect to one another and intersect at a common point 40, preferably at or near the center of the tile 32. The half tiles 32a include the same elements but spaced on a shrunken scale in one dimension.

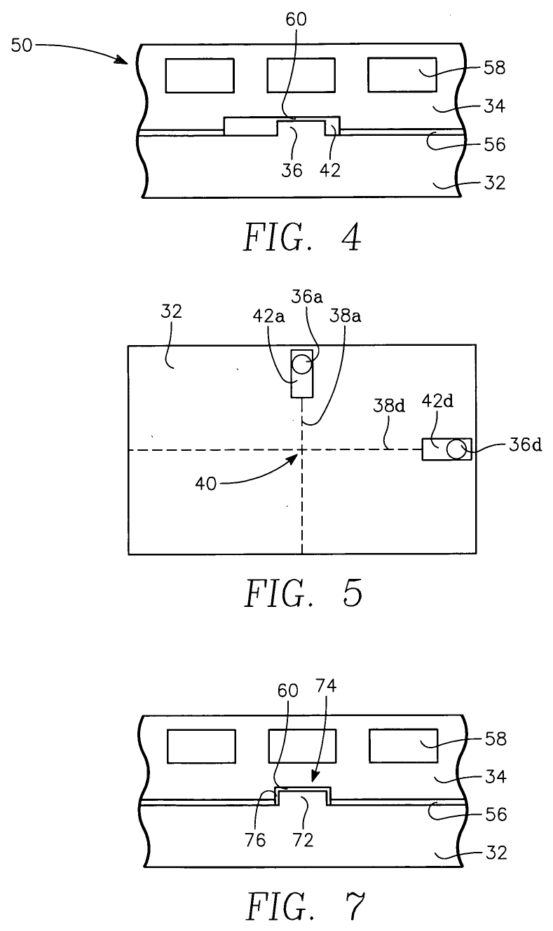

Correspondingly, the side of the backing plate 34 facing the tiles 32 is formed with sets of grooves 42a, 42b, 42c having lengths extending along the axes 38a, 38b, 38c sufficient to capture the corresponding pins 36a, 36b, 36c during movement for any temperature experienced by the target assembly 30 during fabrication or use. The grooves 42a, 42b, 42c have widths that closely accommodate the widths of the tile pins 36a, 36b, 36c so as to guide the pins 36a, 36b, 36c during differential thermal expansion. In FIG. 4 is illustrated a cross-sectional view of a target assembly 50 taken along one centering axis 38. The target tile 32 is bonded to the target backing plate 34 with a thin bonding layer 56, which may be composed of indium, a conductive elastomer, or other suitable thermally and electrically conductive bonding material. The invention is also applicable to autoclaved targets in which no bonding material is required and is useful to guaranteeing alignment during the rigors of autoclave bonding. The backing plate 34 may be composed of multiple layers of a suitable material such as titanium and include cooling channels 58 for a cooling fluid such as chilled water to circulate through to maintain the target assembly 50 at a reasonably low temperature during sputtering.

The target tile 32 is generally planar in its central region but, according to the invention and as illustrated in FIG. 4, it includes a pin 36 extending above its bonded surface and having sufficient length to extend through the bonding layer 56 into a groove 42 formed on the bonded side of backing plate 34. However, a thin clearance 60 exists between the top of the pin 36 and the roof of the groove 42 recess so that the top of the pin 36 does not contact the backing plate 34 and impede the movement of the pin 36 within the groove 42. The height of the pin 36 and the depth of the groove 42 should be relatively small so that the thickness of the backing plate 34 is not unduly increased since an increased thickness disadvantageously attenuates the magnetic field from the magnetron as it penetrates the backing plate 34. Although the target tile 34 is bonded to the backing plate 34, differential thermal expansion and possibly other effects cause some differential movement between the two but the pin 36 is confined to the groove 42 during this motion and thus is guided to move along the illustrated axial direction of the groove 42. In the unillustrated transverse direction, the pin 36 is closely fit within the groove 42 but is not fit tight enough at any temperature experienced by the target assembly 50 to bind and impede movement along the groove's axial direction.

It is thus clear that, with reference to FIG. 3, as the target tiles 32, 32a expand or contact with respect to the backing plate 34, the pins 36 of the tile are confined within the grooves 42 and guided by them to move to or away from the center 40. As a result, the tile 32 is aligned with and centered on the backing plate 34 despite the thermal cycling. The centering and alignment between the tiles 32 and backing plate 34 are also useful during the bonding process. The bonding layer 56 accommodates the relative movement although some stress may build up in the tile 32 or backing plate 34 to absorb some of the relative movement. The centering does not depend upon the bonding layer but upon the mechanical guiding of the pins 36 by the grooves 42. The axial extent of the groove 42 needs to accommodate only the anticipated relative movement of the pin 36 within the groove 42 so the axial length typically needs not be as long as illustrated.

The multiple sets of pins and grooves constrains the sides of the tiles 32 to remain parallel to their original orientations. Further, since the tile center 40 or other point fixed to the intersection point is maintained to a fixed point on the backing plate, the gaps on opposed sides of the tiles 32 do not walk during thermal cycling.

The three sets of pins 36 and grooves 42 provide a mechanically rigid interface between the tiles 32 and the backing plate 34 to thereby minimize tolerances. However, the three sets overly define the center 40 so that, under differential thermal expansion, the center 40 of the tile 32 with respect to the pins 36 may deviate by a small distance from the corresponding center position 40 of the backing plate 34 with respect to the grooves 42. Assuming that both the tiles 32 and backing plate 34 have isotropic coefficients of thermal expansion in the plane of the target, the separation of the centers can be eliminated by requiring the three pins 36a, 36b, 36c to be equidistant from the center 40.

Only two sets of pins and grooves are required to provide the centering mechanism for the tiles 32 although with reduced mechanical tolerances for the parts. For example, the two sets of pins 36a, 36b and grooves 42a, 42b would suffice. Also, the two sets of pins 36b, 36c and grooves 42b, 42c would suffice. In a more preferred arrangement, schematically illustrated in the plan view of FIG. 5, each tile 32 includes the first pin 36a arranged along the centering axis 38a bisecting one dimension of the rectangle and another pin 36d arranged along a centering axis 38d perpendicular to the first center axis 38a and bisecting the second dimension of the rectangle. The first pin 36a fits within the first centering groove 42a extending along the first centering axis 38a and the other pin 36d fits within another centering groove 42d extending along the perpendicular other centering axis 38d. With the arrangement of perpendicular centering axes 38a, 38d, there is substantially no problems with the centers 40 of the tiles 32 and the corresponding points on backing plate 36 deviating from each other. It is not necessary that the two centering axes 38a, 38d bisect the tile 32, but such a restriction reduces the deformation of the bonding layer during thermal cycling.

More than three sets of pins and grooves may be used but they are not considered to be necessary. It is also possible to place two sets of pins and grooves along one centering axis, which would provide increased mechanical rigidity.

It is not necessary that the centering pins 36 be circular. Instead, they may have straight lateral sides extending in parallel to the lateral sides of the grooves 42.

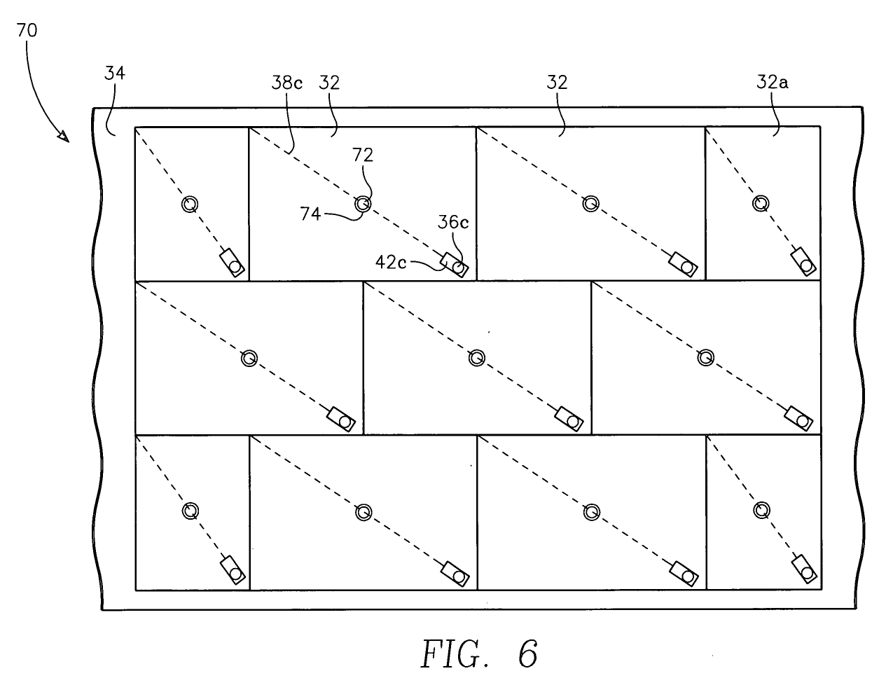

In a second embodiment of the invention schematically illustrated in plan view in FIG. 6, a target assembly 70 includes the multiple tiles 32 bonded to the backing plate 34. Each tile 32 includes the centering pin 36 guided by the centering groove 42c in the backing plate 34, both arranged along the diagonal centering axis 38c. Each tile 32 additionally includes, as further illustrated in the cross-sectional view of FIG. 7, a central pivoting pin 72 slidably fit within a centering hole 74. The pivoting pin 72 is located on the diagonal centering axis 38d and preferably located at the center of the rectangular tile 32, and the centering hole 74 is formed at a corresponding position in the backing plate 34. At least one and preferably both of the centering pin 72 and the centering hole 74 should be circular so that the tile 32 is pivotally guided about the center of the centering hole 74, preferably located at the center of the tile 32. Although FIG. 7 illustrates a distinct clearance 76 between the sides of the pivoting pin 36 and the centering hole 74, the clearance 76 is preferably made as small as possible to minimize the radial movement between the pivoting pin 72 and the centering hole 74 at all temperatures experienced by the assembly but to nonetheless allow free rotation of the pivoting pin 72 within the centering hole 74. The centering operation is still possible if the pivoting pin 72 binds within the centering hole 74 as long as excessive stress is avoided and the sides of the tile 32 are aligned with the perpendicular coordinates of the backing plate 34 when the binding occurs.

The location of the pivoting pin 72 at the tile center on the tile diagonal axis 38c and the location of the centering pin 36c near the end of diagonal axis 38c provides symmetric centering of the sides of the tile 32 and the greatest tolerance for the groove 42c. However, such positions are not necessary as long as the pivoting pin 72 lies on or near the axis of the groove 42c.

Although the invention has been described with reference to rectangular target tiles, other tiles shapes can be utilized in conjunction with the invention.

Although the centering pins are most conveniently composed of target material and formed together with the target tile in its fabrication, it is possible that the centering pins be composed of different material or be fixed to a pre-existing target tile.

Although the invention was developed for sputtering onto glass substrates for flat panel displays, it may be applied to sputtering onto other types of substrates, for example, for solar cells and may also be applied to sputter targets for large circular wafers.

The invention thus assures the centering or alignment of the target tiles on the backing plate and prevents the gap between tiles from growing too large during thermal cycling or incompletely controlled bonding.

1. A target assembly for use in a sputter chamber, comprising:
a backing plate;
a plurality of target tiles bonded to said backing plate; and
a plurality of mechanical centering mechanisms operative between said backing plate and respective ones of said target tiles causing said target tiles to have respective tile points substantially co-positioned with respective centering points of said backing plate and to maintain perpendicular alignment of sides of each of said tiles with respective to others of said tiles.

2. The target assembly of claim 1, wherein each of said mechanical centering mechanisms includes at least one pin extending from a side of a respective tile bonded to said backing plate and a corresponding groove in said backing plate accommodating said pin and allowing movement of said pin along an axis of said groove.

3. The target assembly of claim 2, wherein each of said mechanical centering mechanisms includes a plurality of said pins and a plurality of said grooves extending along respective ones of said axes inclined with respect to each other.

4. The target assembly of claim 3, wherein said axes intersect at a center of said respective tile.

5. The target assembly of claim 2, wherein each of said mechanical centering mechanism includes a second pin and said backing plate includes a centering hole closely accommodating said second pin and located along said axis of said groove.

6. The target assembly of claim 1, wherein said tiles are substantially rectangular.

7. A target assembly for use in a sputtering chamber, comprising:
a backing plate;
a plurality of target tiles bonded to said backing plate in an array and having gaps formed therebetween, each of said tiles including at least a first pin and a second pin extending into a respective first recess and a respective second recess formed in said backing plate, each combination of said first pin and said first recess and of said second pin and second recess allowing relative motion between said tile and said backing plate, at least one of said recesses comprising a groove extending along an axis and closely accommodating a corresponding one of said pins in a direction transverse to said axis.

8. The target assembly of claim 7, wherein both said first and second recesses comprise grooves extending along respective axes inclined with respect to each other.

9. The target assembly of claim 8, wherein said axes intersect at a center of said each tile.

10. The target assembly of claim 7, wherein the other of said recesses comprises a substantially circular recess arranged along said axis.

11. A target assembly for use in a sputter chamber, comprising:
a backing plate;
a plurality of target tiles bonded to said backing plate, each of said tiles including at least one pin extending into a corresponding groove formed in said backing plate and allowing movement of said pin along an axis of said groove.

12. The target assembly of claim 11, wherein each of said tiles includes a plurality of said pins extending into corresponding ones of a plurality of said grooves formed in said backing plate along respective ones of a plurality of said axes.

13. The target assembly of claim 12, wherein said plurality of axes intersect at a center of said each tile.

14. The target assembly of claim 12, wherein there are two of said grooves.

15. The target assembly of claim 14, wherein said axes of said two grooves are perpendicular to each other.

16. The target assembly of claim 12, wherein there are three of said grooves.

17. The target assembly of claim 11, wherein each of said tiles additionally includes a second pin extending into a corresponding centering hole formed in said backing plate and allowing rotation of said second pin in said centering hole.

18. The target assembly of claim 11, wherein said tiles are rectangular.

19. A sputtering chamber, comprising:
a vacuum chamber accommodating a substrate to be sputter coated;
a backing plate sealed to said vacuum chamber;
a plurality of target tiles bonded to said backing plate in an array and having gaps formed therebetween, each of said tiles including at least a first pin and a second pin extending into a respective first recess and a respective second recess formed in said backing plate, each combination of said first pin and said first recess and of said second pin and second recess allowing relative motion between said tile and said backing plate, at least one of said recesses comprising a groove extending along an axis and closely accommodating a corresponding one of said pins in a direction transverse to said axis.

20. The chamber of claim 19, wherein both said first and second recesses comprise grooves extending along respective axes inclined with respect to each other.

21. The chamber of claim 20, wherein said axes intersect at a center of said each tile.

22. The chamber of claim 19, wherein the other of said recesses comprises a substantially circular recess arranged along said axis.

23. The chamber of claim 19, wherein said tiles are substantially rectangular.

24. The chamber of claim 19, wherein said array is a two-dimensional array.
